(19) United States
(12) Patent Application Publication
(10) Pub. No.: US 2025/0026630 A1
(43) Pub. Date: Jan. 23, 2025

(54) INERTIAL SENSOR AND METHOD FOR FORMING THE SAME

(71) Applicant: AAC Technologies Pte. Ltd., Singapore (SG)

(72) Inventors: Veronica Tan, Singapore (SG); Zhan Zhan, Shenzhen (CN); Zaixiang Pua, Singapore (SG); Houming Chong, Johor (MY); Kahkeen Lai, Singapore (SG)

(21) Appl. No.: 18/356,264

(22) Filed: Jul. 21, 2023

(51) Int. Cl. B81B 3/00; B81B 7/00; B81C 1/00; G01P 15/125

(52) U.S. Cl. CPC B81B 3/0051; B81B 7/0035; B81C 1/00277; G01P 15/125; B81B 2201/0228; B81C 2203/0109

(57) ABSTRACT

An inertial sensor and a method therefor are provided. The inertia sensor includes a first substrate; a first insulation layer stacked on the first substrate; a first conducting layer stacked on the first insulation layer and including first openings; stoppers corresponding to the first openings and embedded into the first openings to close the first openings; a second insulation layer stacked on the first conducting layer and including a cavity; a second conducting layer stacked on the second insulation layer and including second openings; a first bonding structure stacked on the second conducting layer; a second substrate; and a second bonding structure stacked on the second substrate, the second bonding structure and the first bonding structure being bonded together to define a closed space therebetween. Thus, a structure thereof remains stable, thereby minimizing the feature size and bringing more room of device performance improvement.

### TECHNICAL FIELD

The present invention relates to the technical field of micro-electromechanical systems, and in particular, to an inertia sensor and a method for forming the inertia sensor.

### BACKGROUND

In the related art, an inertia sensor includes a movable conducting structure and a non-movable conducting structure that are opposite to each other. When the movable conducting structure moves, a distance between the movable conducting structure and the non-movable conducting structure changes, so that a capacitance signal in a corresponding direction can be detected, thereby achieving detection of the inertia.

The non-movable conducting structure is a patterned conducting layer provided with several gaps. During a gap release process, the material beneath the non-movable conducting structure is exposed and partially removed. This also limits the minimum feature size of the non-movable conducting structure and causes the structural instability of the non-movable conducting structure during function, hence negatively affects the final performance of the inertial sensor.

### SUMMARY

In a first aspect, an inertial sensor is provided. The inertia sensor includes: a first substrate; a first insulation layer stacked on the first substrate; a first conducting layer stacked on the first insulation layer and including first openings; stoppers corresponding to the first openings in one-to-one correspondence and embedded into the first openings to close the first openings; a second insulation layer stacked on the first conducting layer and including a cavity; a second conducting layer stacked on the second insulation layer and including second openings; a first bonding structure stacked on the second conducting layer; a second substrate; and a second bonding structure stacked on the second substrate, wherein the second bonding structure and the first bonding structure are bonded together, and a closed space is formed between the second substrate and the first substrate.

In an improved embodiment, the stoppers are stacked on a surface of the first conducting layer facing the cavity.

In an improved embodiment, at least two of the stoppers located at the first conducting layer are sequentially arranged at intervals along a radial direction of the first conducting layer.

In an improved embodiment, one of the stoppers includes an embedded portion and a lamination portion, and wherein the embedded portion extends into a corresponding first opening of the first openings to forming a sealing fit, and the lamination portion abuts against the first conducting layer.

In an improved embodiment, the embedded portion is located at a bottom center position of the lamination portion.

In an improved embodiment, each of the stoppers is made of a non-conductive material.

In an improved embodiment, the non-conductive material of each of the stoppers is silicon nitride.

In an improved embodiment, a first pressure point is formed in the second conducting layer, and a second pressure point is stacked on the second conducting layer, and wherein the second pressure point is electrically connected to the first conducting layer through the first pressure point.

In an improved embodiment, a surface of the second substrate facing the first substrate is recessed to a recess.

In a second aspect, a method for forming an inertial sensor is provided. The inertia sensor includes: a first substrate; a first insulation layer stacked on the first substrate; a first conducting layer stacked on the first insulation layer and including first openings; stoppers corresponding to the first openings in one-to-one correspondence and embedded into the first openings to close the first openings; a second insulation layer stacked on the first conducting layer and including a cavity; a second conducting layer stacked on the second insulation layer and including second openings; a first bonding structure stacked on the second conducting layer; a second substrate; and a second bonding structure stacked on the second substrate, wherein the second bonding structure and the first bonding structure are bonded together, and a closed space is formed between the second substrate and the first substrate. The method includes: forming the first insulation layer and the first conducting layer at the first substrate, and forming the first openings at the first conducting layer; forming the stoppers at the first conducting layer, the stoppers being embedded into the first opening; forming the second insulation layer at the first conducting layer; forming the second conducting layer at the second insulation layer, forming the second opening at the second conducting layer; forming the cavity at the second insulation layer; forming the first bonding structure at the second conducting layer; forming the second bonding structure on the second substrate; and bonding the first bonding structure and the second bonding structure together at a high temperature, a closed space being formed between the second substrate and the first substrate.

### BRIEF DESCRIPTION OF DRAWINGS

FIG. 1 is a schematic structural diagram of an inertia sensor according to a first embodiment of the present invention;

FIG. 2 is a schematic structural view of a stopper of a structure according to the first embodiment 1 of the present invention;

FIG. 3 is a schematic structural view of a stopper of another structure according to the first embodiment of the present invention;

FIG. 4a to FIG. 4i are schematic diagrams for forming the inertia sensor according to the first embodiment of the present invention;

FIG. 5 is a schematic structural diagram of an inertia sensor according to a second embodiment of the present invention; and

FIG. 6a to FIG. 6i are schematic diagrams for forming the inertia sensor according to the first embodiment of the present invention;

### REFERENCE NUMERALS

1 First substrate;
2 First insulation layer;
3 First conducting layer;
4 First opening;
5 Stopper;
51 Embedded portion;
52 Lamination portion;
6 Second insulation layer;
7 Cavity;
8 Second conducting layer;
9 Second opening;
10 Movable mass;
11 First pressure point;
12 Second pressure point;
13 First bonding structure;
14 Second substrate;
15 Second bonding structure; and
16 Recess.

### DESCRIPTION OF EMBODIMENTS

The embodiments described below by referring to the accompanying figures are exemplary only for explaining the present invention, and shall not be construed as limiting the present invention.

### First Embodiment

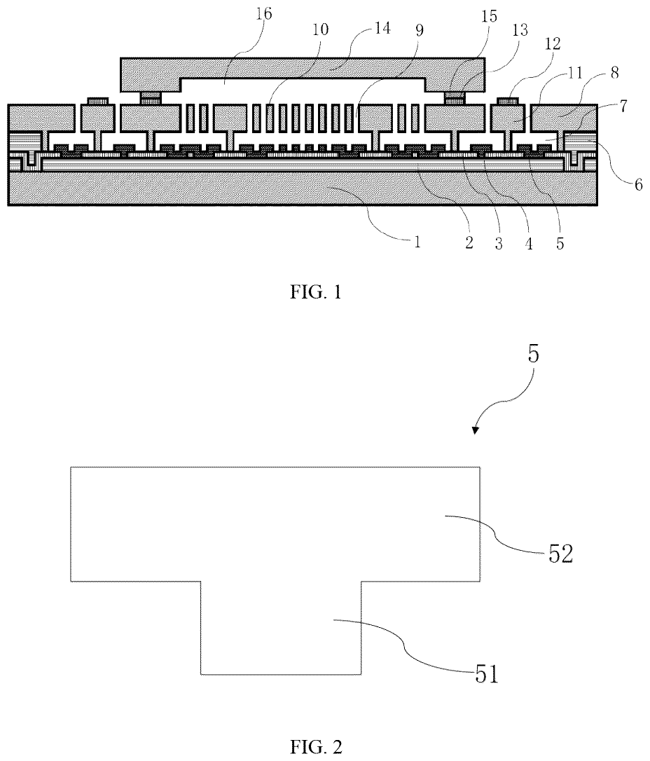

As shown in FIG. 1 to FIG. 3, an embodiment of the present invention provides an inertia sensor, including: a first substrate 1, a first insulation layer 2, a first conducting layer 3, a stopper 5, a second insulation layer 6, a second conducting layer 8, a first bonding structure 13, a second substrate 14, and a second bonding structure 15.

The first substrate 1 is a semiconductor substrate, such as a silicon substrate. In an implementation manner, the first substrate 1 is circular. Those skilled in the art should know that the first substrate 1 may also be in other shapes, such as a square, etc., which will not be limited herein.

The first insulation layer 2 is stacked on the first substrate 1. A shape of the first insulation layer 2 is adapted to the shape of the first substrate 1. The first insulation layer 2 is configured to support the first conducting layer 3 and make the first conducting layer 3 be electrically isolated from the first substrate 1. In an implementation manner, the first insulation layer 2 is made of a material including silicon dioxide.

The first conducting layer 3 is stacked on the first insulation layer 2. A shape of the first conducting layer 3 is adapted to the shape of the first insulation layer 2. The first conducting layer 3 includes first openings. The first opening 4 is an annular recess structure. The first openings 4 are sequentially arranged at intervals around an axis of the first conducting layer 3. Adjacent first openings 4 may have a same inner diameter or different inner diameters, which will not be limited herein. The first conducting layer 3 is made of a conductive material, such as polysilicon.

The stopper 5 is an annular structure. The stoppers 5 are arranged at intervals around the axis of the first conducting layer 3. The stoppers 5 correspond to the first openings 4 in one-to-one correspondence. The stopper 5 is embedded into the first opening 4 to close the first opening 4, so that the first insulation layer 2 beneath the first conducting layer 3 can maintain integrity during the forming process, and a structure thereof can remain stable, and there is no limitation on the structures of the first conducting layer 3 and the second conducting layer 8, thereby minimizing the feature size and bringing more room of device performance improvement.

The stopper 5 is a made of a non-conductive material to avoid possible electrical short circuit and damage when a surface of the first conducting layer 3 is in direct contact with a surface of the stopper 5. In an implementation manner, the material of the stopper 5 may be silicon nitride.

A shape of the second insulation layer 6 is adapted to the shape of the first conducting layer 3. The second insulation layer 6 is stacked on the first conducting layer 3. A material of the second insulation layer 6 is silicon dioxide. The second insulation layer 6 is configured to support the second conducting layer 8, and to make the first conducting layer 3 be electrically isolated from the second conducting layer 8. The second insulation layer 6 includes a cavity 7. In an implementation manner, the cavity 7 is an annular recess structure, and an axis of the annular recess structure is coincident with an axis of the first conducting layer 3.

The second conducting layer 8 is stacked on the second insulation layer 6. A shape of the second conducting layer 8 is adapted to the shape of the second insulation layer 6. The second conducting layer 8 includes second openings 9. The second opening 9 is an annular recess structure. The second openings 9 are arranged at intervals around an axis of the second conducting layer 8. Adjacent second openings 9 may have a same inner diameter or different inner diameters, which will not be limited herein. The second conducting layer 8 is made of a conductive material, such as polysilicon.

The second conducting layer 8 above the cavity 7 is a movable mass 10. When the movable mass 10 moves, a distance between the movable mass 10 and the first conducting layer 3 changes, so that a capacitance signal in a corresponding direction can be detected, thereby achieving detection of the inertia.

The deflection of the second conducting layer 8 is parabolic, and the deflection of the second conducting layer 8 at a circle center position is the largest and the deflection of the second conducting layer 8 at an edge position is the smallest. Therefore, the movable mass 10 is arranged at position where the second conducting layer 8 has the most violent movement, i.e., a center position of the second conducting layer 8, so as to improve the sensitivity of the inertial sensor.

The first bonding structure 13 has an annular shape, and the first bonding structure 13 is stacked on the second conducting layer 8.

The second substrate 14 is a semiconductor substrate, such as a silicon substrate. In an implementation manner, the second substrate 14 is circular. Those skilled in the art should know that the second substrate 14 can also be in other shapes, such as square, etc., which will not be limited herein.

The second bonding structure 15 has an annular shape. The second bonding structure 15 is stacked on the second substrate 14. A position of the second bonding structure 15 corresponds to a position of the first bonding structure 13. The second bonding structure 15 and the first bonding structure 13 are bonded together, and the second substrate 14 and the first substrate 1 form a closed space. Therefore, an internal structure of the inertia sensor can be prevented from being interfered by the external environment, which is beneficial to controlling an air pressure in the cavity and thus improving the working stability.

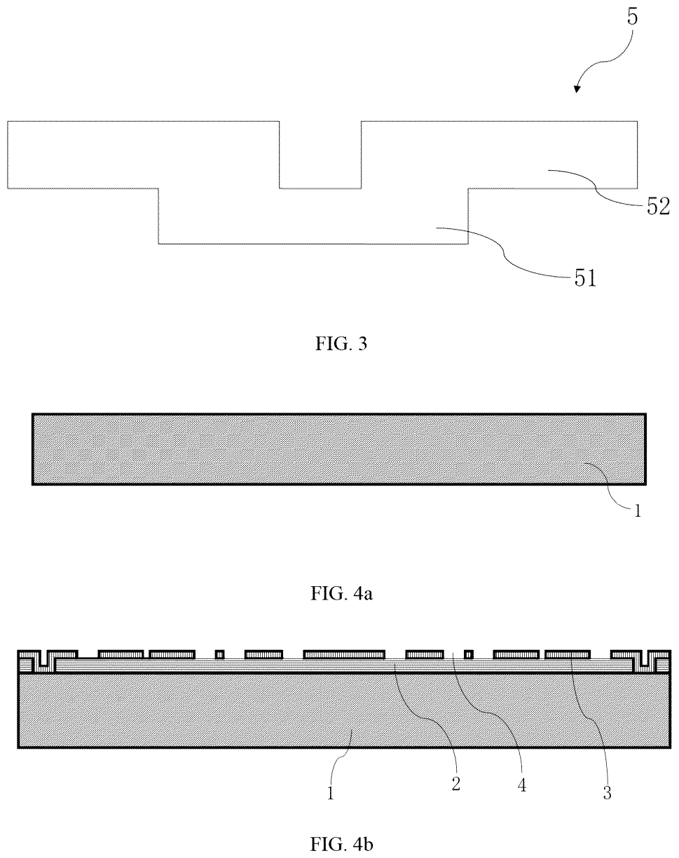

With reference to FIG. 2 and FIG. 3, a cross-section of the stopper 5 is a “T”-like structure. The stopper 5 includes an embedded portion 51 and a lamination portion 52, which are preferably integrally formed. The embedded portion 51 is located at a bottom center position of the lamination portion 52. A cross-sectional shape of each of the embedded portion 51 and the lamination portion 52 is rectangular. Those skilled in the art should know that the cross-sectional shape of each of the embedded portion 51 and the lamination portion 52 can also be other shapes, for example circle, ellipse, triangle and regular polygon, which will not be limited herein.

The embedded portion 51 extends into the first opening 4 to form a sealed fit, and an outer diameter of the embedded portion 51 is adapted to an inner diameter of the first opening 4. The embedded portion 51 is embedded into the first opening 4, which is beneficial to improving the shear strength of the stopper 5, and preventing the stopper 5 from peeling off.

The lamination portion 52 abuts against the first conducting layer 3, which is beneficial to spreading out the large interacting stress among different materials, thus preventing the stopper 5 from peeling off.

In this embodiment, the stopper 5 is designed as a small-area structure, rather than a large-area film coverage structure, so as to cut off the film stress influence across whole device and reduce the effect on the overall warpage.

A first pressure point is formed in the second conducting layer 8, and the first pressure point 11 is separated from the movable mass 10. A second pressure point 12 is stacked on the second conducting layer 8, and the second pressure point 12 is electrically connected to the first conducting layer 3 through the first pressure point 11. The second pressure point 12 is used for subsequent package wiring, and the second pressure point 12 and the first bonding structure 13 are formed in a same process.

Further, a surface of the second substrate 14 facing the first substrate 1 is recessed to form a recess 16. The recess 16 is located at a center position of the second substrate 14. The recess 16 is a circular recess, and an axis of the circular recess is coincident with an axis of the second substrate 14. The second bonding structure 15 is located at an outer side of the recess 16.

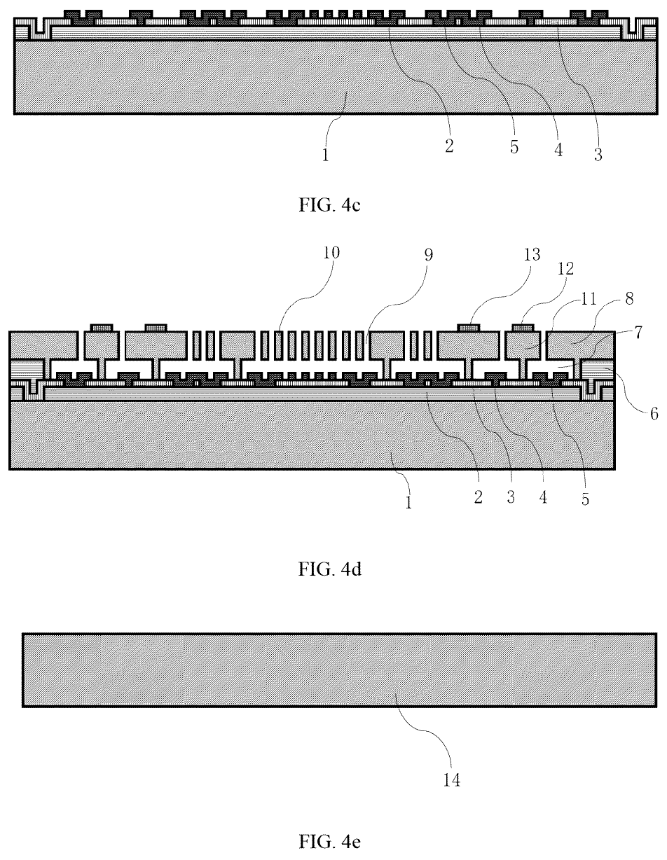

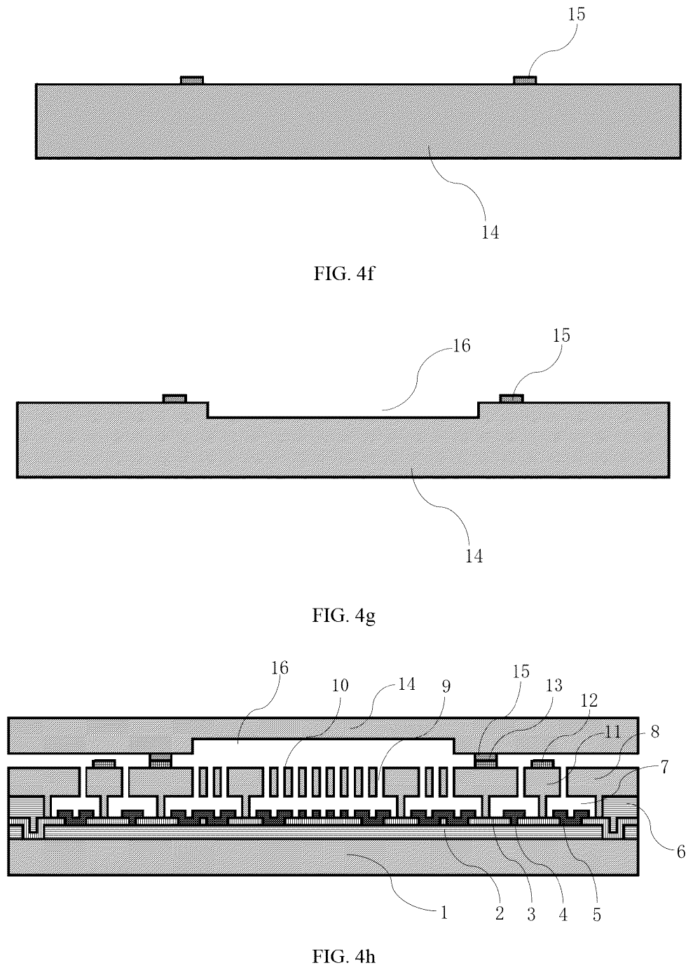

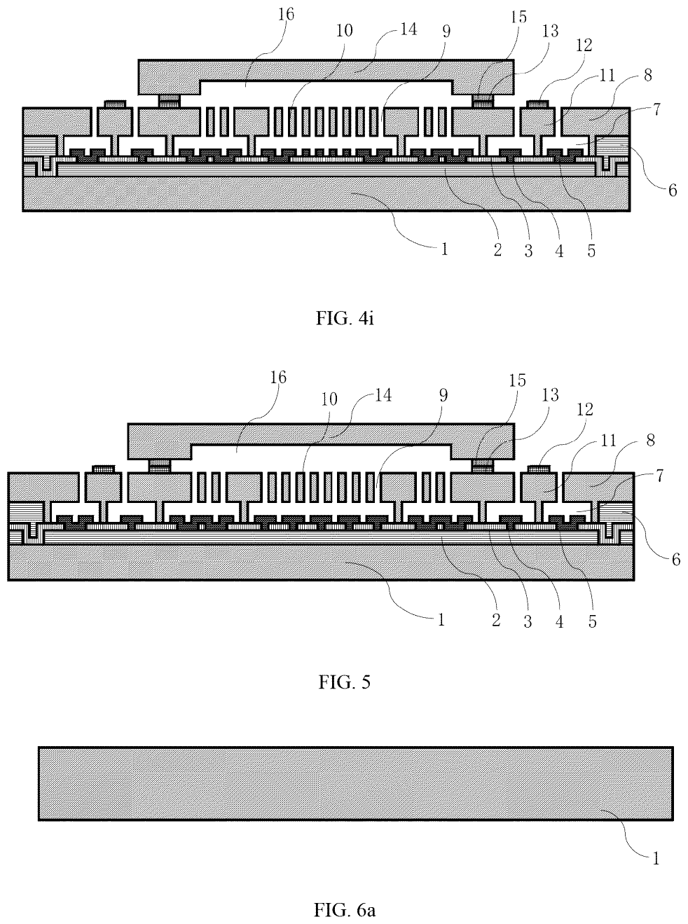

FIG. 4a to FIG. 4i are schematic diagrams for forming the inertia sensor according to the first embodiment of the present invention. The method includes the following steps.

At S101, with reference to FIG. 4a and FIG. 4b, a first insulation layer 2 and a first conducting layer 3 are formed on a first substrate 1, and a first opening 4 is formed in the first conductive layer 3.

At this step, the first insulation layer 2 is formed at the first substrate 1 by depositing, the first conductive layer 3 is formed at the first insulating layer 2 by depositing, and an etchant resist layer is formed at a surface of the first conducting layer 3 by depositing, the etchant resist layer is patterned by a photolithography process to form a mask, and the first conducting layer 3 is etched through the mask to form the first openings 4 penetrating through the first conducting layer 3.

At S102, with reference to FIG. 4c, stoppers 5 are formed at the first conducting layer 3, and the stoppers 5 are embedded into the first openings 4, at this step, the stoppers 5 are formed by depositing, the stoppers 5 are embedded into the first openings 4 and are located above a large area of the first conducting layer 3.

At S103, with reference to FIG. 4d, a second insulation layer 6 is formed at the first conducting layer 3 by depositing.

At S104, with reference to FIG. 4d, a second conducting layer 8 is formed at the second insulation layer 6, and second openings 9 are formed at the second conducting layer 8.

At this step, the second conducting layer 8 is formed at the second substrate 14 by depositing, an etchant resist layer is formed at a surface of the second conducting layer 8 by depositing, the etchant resist layer is patterned by a photolithography process to form a mask, and the second conducting layer 8 is etched through the mask to form the second openings 9 penetrating through the second conducting layer 8.

At S105, with reference to FIG. 4d, a cavity 7 is formed at the second insulation layer 6. At this step, the second insulation layer 6 is etched by using a gas phase hydrofluoric acid to form the cavity 7. Since the stoppers 5 are embedded into the first openings 4, thereby preventing the gas phase hydrofluoric acid from eroding the first insulation layer 2 from the first openings 4, and thus ensuring the integrity of the first insulation layer 2 and maintaining a stable structure.

At S106, with reference to FIG. 4d, a first bonding structure 13 is formed at the second conducting layer 8. At this step, the first bonding structure 13, a first pressure point 11 and a second pressure point 12 are formed at a surface of the second conducting layer 8, for example, by depositing and etching.

At step S107, with reference to FIG. 4e to FIG. 4g, a second bonding structure 15 is formed at the second substrate 14, and the second bonding structure 15 is formed at a surface of the second substrate 14, for example, by depositing and etching.

At this step, an etchant resist layer is formed at a bottom surface of the second substrate 14, the etchant resist layer is patterned by a photolithography process to form a mask, the second substrate 14 is etched through the mask to form a recess 16.

At step S108, with reference to FIG. 4h and FIG. 4i, the first bonding structure 13 and the second bonding structure 15 are bonded together at a high temperature, and a closed space is formed between the second substrate 14 and the first substrate 1, and finally a part of the second substrate 14 is removed to expose the second pressure point 12.

### Second Embodiment

In this embodiment, there is a large area at a center position of the first conducting layer 3 that is not provided with a first opening 4. As shown in FIG. 5, a stopper 5 is stacked on a surface of the first conducting layer 3 facing the cavity 7. The stopper 5 is not only embedded into the first opening 4, but when there is a large area of the first conducting layer 3 between two first openings 4, several stoppers 5 can be provided to cover the surface of the first conducting layer 3, thereby avoiding possible electrical short circuits and damage due to the surface of the movable mass 10 being in direct contact with the surface of the first conducting layer 3 when the two movable paths are greatly deformed.

In this embodiment, some stoppers 5 provided at the first conducting layer 3 are sequentially arranged at intervals along a radial direction of the first conducting layer 3, and the distances between adjacent ones of these several stoppers 5 are the same.

Based on the inertia sensor provided in the above embodiments, the present invention further provides a method for forming the inertia sensor, and the method includes the following steps.

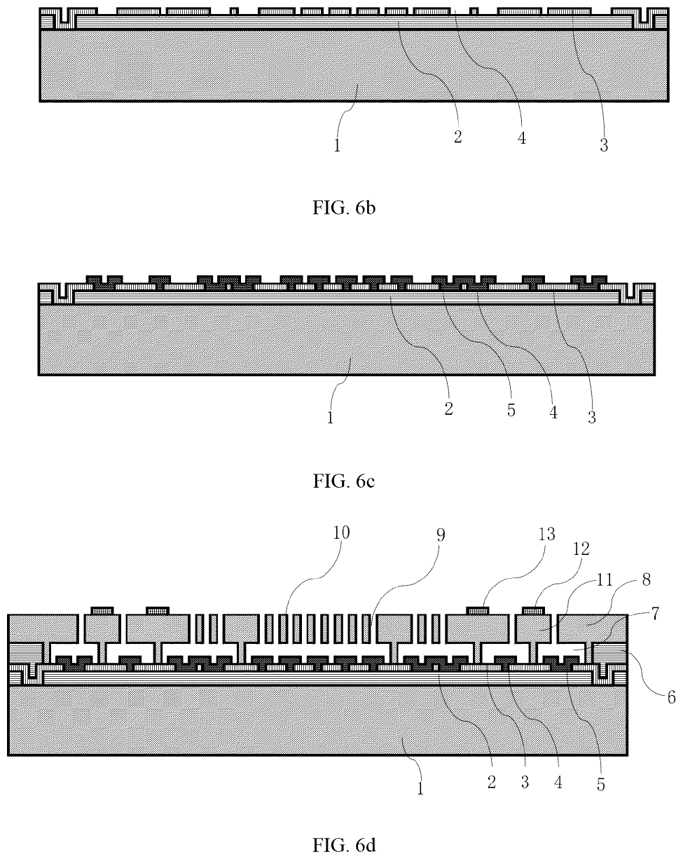

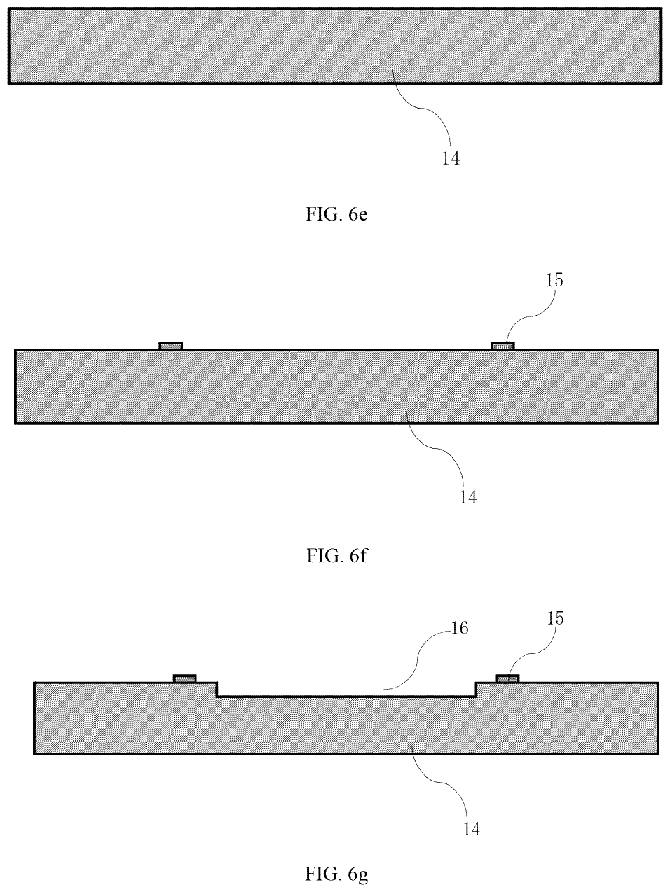

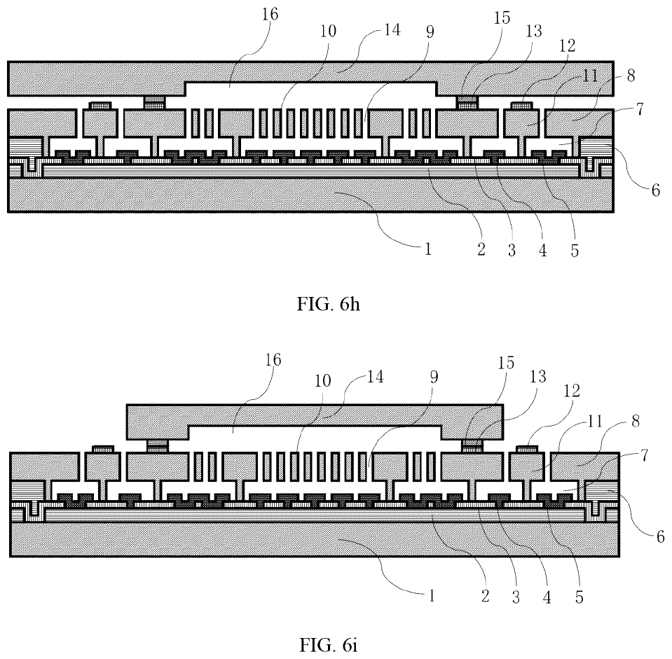

At step S101, with reference to FIG. 6a and FIG. 6b, a first insulation layer 2 and a first conducting layer 3 are formed at the first substrate 1, and first openings 4 are formed at the first conducting layer 3.

At this step, the first insulation layer 2 is formed at the first substrate 1 by depositing, the first conducting layer 3 is formed at the first insulation layer 2 by depositing, and an etchant resist layer is formed at a surface of the first conducting layer 3 by depositing, the etchant resist layer is patterned by a photolithography process to form a mask, and the first conducting layer 3 is etched through the mask to form the first openings 4 penetrating through the first conducting layer 3.

At step S102, with reference to FIG. 6c, stoppers 5 are formed at the first conducting layer 3, and the stoppers 5 are embedded into the first openings 4, at this step, the stoppers 5 are formed by depositing, the stoppers 5 are embedded into the first openings 4 and are located above a large area of the first conducting layer 3.

At step S103, with reference to FIG. 6d, a second insulation layer 6 is formed at the first conducting layer 3 by depositing.

At step S104, with reference to FIG. 6d, a second conducting layer 8 is formed at the second insulation layer 6, and second openings 9 are formed at the second conducting layer 8.

At this step, the second conducting layer 8 is formed at the second substrate 14 by depositing, an etchant resist layer is formed at a surface of the second conducting layer 8 by depositing, the etchant resist layer is patterned by a photolithography process to form a mask, and the second conducting layer 8 is etched through the mask to form the second openings 9 penetrating through the second conducting layer 8.

At step S105, with reference to FIG. 6d, a cavity 7 is formed at the second insulation layer 6. At this step, the second insulation layer 6 is etched by using a gas phase hydrofluoric acid to form the cavity 7. Since the stoppers 5 are embedded into the first openings 4, thereby preventing the gas phase hydrofluoric acid from eroding the first insulation layer 2 from the first openings 4, and thus ensuring the integrity of the first insulation layer 2 and maintaining a stable structure.

At step S106, with reference to FIG. 6d, a first bonding structure 13 is formed at the second conducting layer 8. At this step, the first bonding structure 13, a first pressure point 11 and a second pressure point 12 are formed at a surface of the second conducting layer 8, for example, by depositing and etching.

At step S107, with reference to FIG. 6e to FIG. 6g, a second bonding structure 15 is formed at the second substrate 14, and the second bonding structure 15 is formed at a surface of the second substrate 14, for example, by depositing and etching.

At this step, an etchant resist layer is formed at a bottom surface of the second substrate 14, the etchant resist layer is patterned by a photolithography process to form a mask, the second substrate 14 is etched through the mask to form a recess 16.

At step S108, with reference to FIG. 6h and FIG. 6i, the first bonding structure 13 and the second bonding structure 15 are bonded together at a high temperature, and a closed space is formed between the second substrate 14 and the first substrate 1, the first bonding structure 13 and the second bonding structure 15 are bonded together at a high temperature, and finally a part of the second substrate 14 is removed to expose the second pressure point 12.

The structure, features and effects of the present invention have been described in detail above based on the embodiments shown in the drawings. It should be noted that, the above descriptions are merely preferred embodiments of the present invention, and the present invention is not limited to the embodiments as shown in the drawings. Any changes or modifications made according to the concept of the present invention within a spirit covered by the description and drawings shall fall within a scope of the present invention.

What is claimed is:

1. An inertia sensor, comprising:
a first substrate;
a first insulation layer stacked on the first substrate;
a first conducting layer stacked on the first insulation layer and comprising first openings;
stoppers corresponding to the first openings in one-to-one correspondence and embedded into the first openings to close the first openings;
a second insulation layer stacked on the first conducting layer and comprising a cavity;
a second conducting layer stacked on the second insulation layer and comprising second openings;
a first bonding structure stacked on the second conducting layer;
a second substrate; and
a second bonding structure stacked on the second substrate, the second bonding structure and the first bonding structure being bonded together, and a closed space being formed between the second substrate and the first substrate.

2. The inertia sensor as described in claim 1, wherein the stoppers are stacked on a surface of the first conducting layer facing the cavity.

3. The inertia sensor as described in claim 2, wherein at least two of the stoppers located at the first conducting layer are sequentially arranged at intervals along a radial direction of the first conducting layer.

4. The inertia sensor as described in claim 1, wherein one of the stoppers comprises an embedded portion and a lamination portion, and wherein the embedded portion extends into a corresponding first opening of the first openings to forming a sealing fit, and the lamination portion abuts against the first conducting layer.

5. The inertia sensor as described in claim 4, wherein the embedded portion is located at a bottom center position of the lamination portion.

6. The inertia sensor as described in claim 1, wherein each of the stoppers is made of a non-conductive material.

7. The inertia sensor as described in claim 6, wherein the non-conductive material of each of the stoppers is silicon nitride.

8. The inertia sensor as described in claim 1, wherein a first pressure point is formed in the second conducting layer, and a second pressure point is stacked on the second conducting layer, and wherein the second pressure point is electrically connected to the first conducting layer through the first pressure point.

9. The inertia sensor as described in claim 1, wherein a surface of the second substrate facing the first substrate is recessed to a recess.

10. A method for forming an inertia sensor,
wherein the inertia sensor comprises:
a first substrate;
a first insulation layer stacked on the first substrate;
a first conducting layer stacked on the first insulation layer and comprising first openings;
stoppers corresponding to the first openings in one-to-one correspondence and embedded into the first openings to close the first openings;
a second insulation layer stacked on the first conducting layer and comprising a cavity;
a second conducting layer stacked on the second insulation layer and comprising second openings;
a first bonding structure stacked on the second conducting layer;
a second substrate; and
a second bonding structure stacked on the second substrate, the second bonding structure and the first bonding structure being bonded together, and a closed space being formed between the second substrate and the first substrate,
and,
wherein the method comprises:
forming the first insulation layer and the first conducting layer at the first substrate, and forming the first openings at the first conducting layer;
forming the stoppers at the first conducting layer, the stoppers being embedded into the first opening;
forming the second insulation layer at the first conducting layer;
forming the second conducting layer at the second insulation layer, forming the second opening at the second conducting layer;
forming the cavity at the second insulation layer;
forming the first bonding structure at the second conducting layer;
forming the second bonding structure on the second substrate; and
bonding the first bonding structure and the second bonding structure together at a high temperature, a closed space being formed between the second substrate and the first substrate.
